(19) United States
(12) Patent Application Publication
(10) Pub. No.: US 2010/0127635 A1
(43) Pub. Date: May 27, 2010

(54) OPTOELECTRONIC DEVICE

(76) Inventor: Chiu-Lin YAO, Hsinchu City (TW)

Correspondence Address: Muncy, Geissler, Olds & Lowe, PLLC, 4000 Legato Road, Suite 310, FAIRFAX, VA, 22033, US

(21) Appl. No.: 12/626,792

(22) Filed: Nov. 27, 2009

(30) Foreign Application Priority Data
Nov. 27, 2008 (TW) 097146119

(51) Int. Cl. H05B 41/36; H01L 33/00; G09F 13/08

(52) U.S. Cl. 315/291; 257/98; 362/97.1; 257/E33.067

(57) ABSTRACT

An optoelectronic device is provided and includes a substrate, a p-type cladding layer, an active layer and a conductive light extraction unit. The conductive light extraction unit includes an n- type cladding layer above the active layer, a metal layer above the n-type cladding layer and a plurality of holes passing through the metal layer and the n-type cladding layer. Sizes of the plurality of holes are not the same and/or the holes are arranged irregularly.

### BACKGROUND

1. Technical Field

The present application relates to a structure of optoelectronic devices, and more particularly to a structure of a light emitting diode having a conductive light extraction layer.

2. Reference to Related Application

This application claims the right of priority based on TW application Ser. No. 097146119, filed Nov. 27, 2008, entitled “OPTO-ELECTRONIC DEVICE”, and the contents of which are incorporated herein by reference.

3. Description of Related Art

Optoelectronic semiconductor devices are devices emitting light from the combination of electrons and holes excited by an external voltage. Optoelectronic semiconductor device is a tiny solid-state light source. It not only has small size, long life, low driving voltage, quick response rate, and good shock-resistance, but also is able to meet the demand for light, thin and small-scale equipment, thereby becoming common products in daily life.

FIG. 1 shows a general structure of the optoelectronic device made of AlGaInP material, including a p-type GaP substrate 10, a p-type AlGaInP cladding layer 11, an active layer 12, an n-type AlGaInP cladding layer 13, and a metal layer 14. Two electrodes 15, 16 are respectively disposed on upper side and lower side of the optoelectronic device.

The above-mentioned metal layer 14 helps to spread the current from the electrodes 15 to the whole device evenly to increase the luminous efficiency, but at the same time, the metal layer 14 absorbs light generated from the active layer 12, thereby impact the efficiency of light extraction. When the area of the metal layer 14 is increased, the current can be spread further, however, the shade area is also increased. Or the shade area can be reduced, but the current is accumulated under the electrode 15. The dilemma produced by the metal layer 14 is an issue that needs to be resolved.

In addition, the above-mentioned optoelectronic devices can be further combined with other devices to form a light-emitting apparatus. Such light-emitting apparatus typically includes a sub-mount containing a circuit. The photoelectric device is bonded to the sub-mount by solder to connect the substrate of the optoelectronic device with the electric circuit on the sub-mount. The above-mentioned sub-mount may be a lead-frame or a large-size mounting substrate to facilitate the layout of the circuit in the light-emitting apparatus and the heat dissipation thereof.

### SUMMARY

The present application provides an optoelectronic device that distributes current uniformly without impacting light extraction efficiency. The optoelectronic device includes a substrate, and a first cladding layer, an active layer and a conductive light extraction unit formed on the substrate. The conductive light extraction unit includes a second cladding layer formed on the active layer and a metal layer formed the second cladding layer. Moreover, a plurality of openings is defined in the metal layer and extends to the second cladding layer to form a plurality of holes. The size of each of the plurality of holes is different or the distribution of the plurality of holes is irregular so that light can be evenly extracted.

In another embodiment of the present application, the optoelectronic device further includes a finger-like conductive body having a junction portion and an extension portion extending outwards from the junction portion. The junction portion is located between the first electrode and the metal layer.

In yet another embodiment of the present application, the optoelectronic device further includes a protective layer covering the metal layer. The protective layer fills the holes to keep the optoelectronic device from being contaminated by water, oxygen or dust in the air.

In another embodiment of the present application, the optoelectronic device further includes a transparent conductive layer disposed between the metal layer and the first electrode. The transparent conductive layer covers the metal layer and fills the holes to block water or oxygen in the air so that the uniformity of the current distribution is enhanced.

In the present application, as a result of the holes defined in the conductive light extraction unit, the current can be uniformly distributed not only in the horizontal direction but also in the vertical direction. In addition, light emitted by the active layer is extracted through the holes so that the light extraction efficiency of the optoelectronic device can be effectively increased.

### BRIEF DESCRIPTION OF THE DRAWINGS

The accompanying drawings are included to provide easy understanding of the application, and are incorporated herein and constitute a part of this specification. The drawings illustrate embodiments of the application and, together with the description, serve to illustrate the principles of the application.

FIG. 1 is a cross-sectional view of a conventional optoelectronic device;

FIG. 2 is a cross-sectional view of the optoelectronic device in accordance with a first embodiment of the present application;

FIG. 3 is a top view of the optoelectronic device in accordance with the first embodiment of the present application;

FIG. 4 is a top view of the optoelectronic device in accordance with a second embodiment of the present application;

FIG. 5 is a cross-sectional view of the optoelectronic device in accordance with the second embodiment of the present application;

FIG. 6 is a cross-sectional view of the optoelectronic device in accordance with a third embodiment of the present application;

FIG. 7 is a cross-sectional view of the optoelectronic device in accordance with a fourth embodiment of the present application;

FIG. 8 is a cross-sectional view of the optoelectronic device in accordance with a fifth embodiment of the present application;

FIG. 9 is a relation schematic view of all the layers in a conductive light extraction unit of the optoelectronic device;

FIG. 10 is a structural view of the optoelectronic device in accordance with a sixth embodiment of the present application;

FIG. 11 is a structure view of a backlight module apparatus of the present application; and

FIG. 12 is a structure view of an illumination apparatus of the present application.

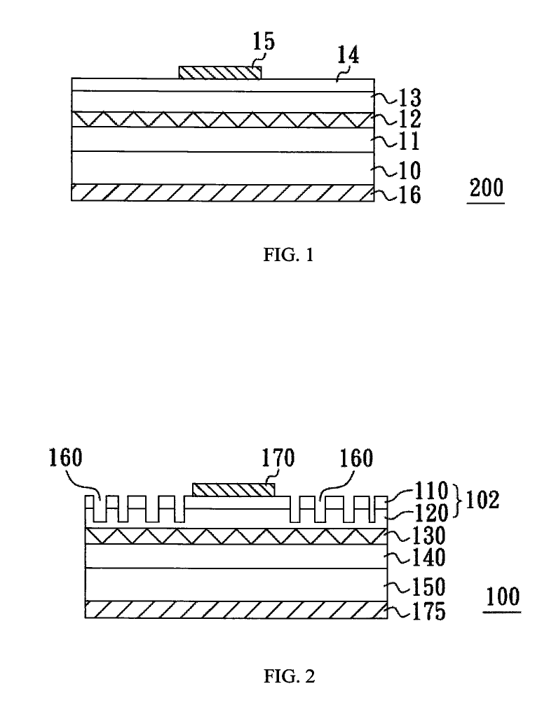

### DESCRIPTION OF THE EMBODIMENTS

Reference is made in detail to the embodiments of the present application, examples of which are illustrated in the accompanying drawings. Wherever possible, the same reference numbers are used in the drawings and the description to refer to the same or like parts.

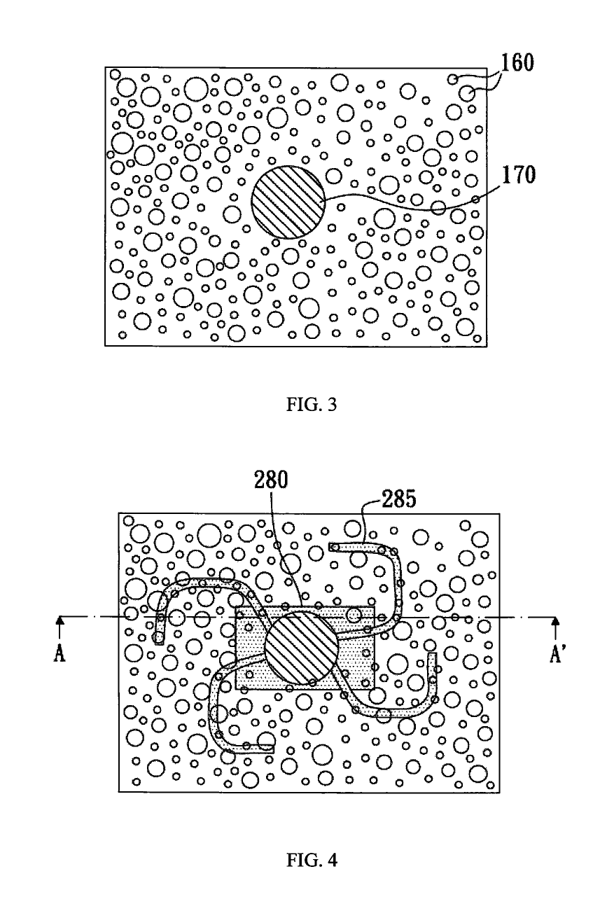

FIG. 2 shows a structural view of an optoelectronic device in accordance with a first embodiment of the present application. The optoelectronic device 100 mainly includes a substrate 150 made of GaP material, a p-type cladding layer 140 formed on the substrate 150, an active layer 130 (or light-emitting layer), and a conductive light extraction unit 102; and further includes a first and second electrodes 170, 175 respectively located on the upper and lower sides of the optoelectronic device 100. The conductive light extraction unit 102 includes an n-type cladding layer 120 formed on the active layer 130, and a metal layer 110 formed on the n-type cladding layer 120. Moreover, a plurality of holes 160 is defined in the metal layer 110 and the n-type cladding layer 120. FIG. 3 shows a top view of the optoelectronic device 100. As FIG. 3 shows, the first electrode 170 is located in the center area of the optoelectronic device 100, and the holes 160 are shown as dots around the first electrode 170. The holes 160 shown in FIG. 3 have different sizes and are deposed irregularly.

When a voltage is applied to the optoelectronic device 100, the conductive light extraction unit 102 can make the current spread to the whole optoelectronic device 100 evenly to make the active layer 130 emit light uniformly. Thus, the current crowding effect is reduced and the light-emitting efficiency of the optoelectronic device 100 is increased. At the same time, the holes 160 are designed to enhance the light extraction efficiency of the active layer 130. Also, the light extraction angle and light field can be adjusted by the irregular arrangement of the holes 160. Thus, the optoelectronic device 100 with a specific light field, high light emitting efficiency and high light extraction efficiency is obtained.

In the embodiment, the n-type cladding layer 120 is made of n-type AlGaInP material. The active layer 130 can be a structure of double heterostructure or multi-layer quantum well structure. The p-type cladding layer 140 is made of p-type AlGaInP material. The metal layer 110 may be formed by e-beam, sputtering or other chemical deposition methods with material includes at least one of the following elements such as titanium, gold, zinc, indium, nickel, beryllium or any combination thereof, and the thickness of the metal layer 110 is so thin that light can penetrate.

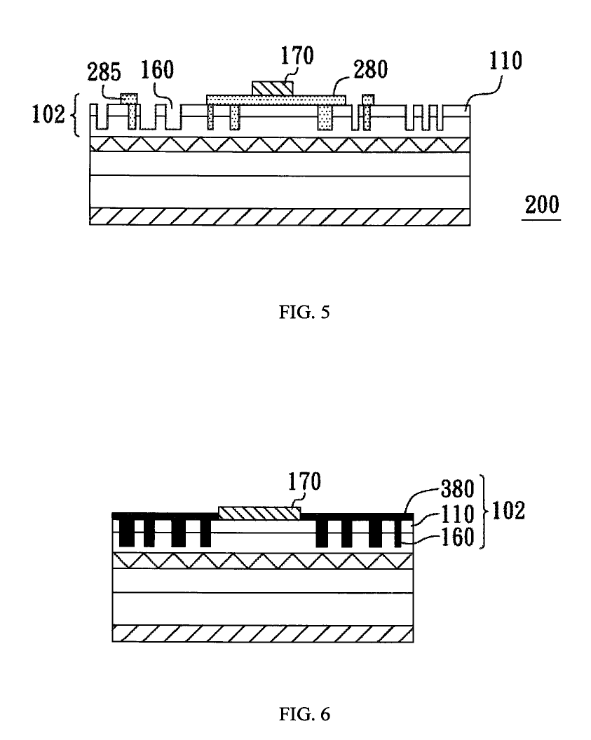

FIGS. 4 and 5 show a structural view of an optoelectronic device in accordance with a second embodiment of the present application. FIG. 5 is a sectional view of the device shown in FIG. 4 along the A-A′ direction. The optoelectronic device 200 in accordance with the second embodiment is similar to the optoelectronic device 100 in accordance with the first embodiment, and the difference between the second embodiment and the first embodiment lies in the conductive light extraction unit 102 that further includes a finger-like conductive body located between the first electrode 170 and the metal layer 110, and contains a junction portion 280 and an extension portion 285 extending outwards from the junction portion 280. FIG. 4 shows one example of the finger-like conductive body. As also shown in FIG. 5, the holes 160 below the extension portion 285 are filled up. The extension portion 285 and the junction portion 280 are made of metal, and may be the same material as the first electrode 170, or other better conductive materials. In one of the embodiments, the material can be gold, silver, copper, aluminum and so on. Due to the better conductivity of the finger-like conductive body, the current can be conducted quickly and traversely by the extension portion 285 to avoid the localized current distribution. Consequently, the current spreads more uniformly and faster.

FIG. 6 shows a structural view of the optoelectronic device in accordance with a third embodiment of the present application. The difference between the third embodiment and the first embodiment lies in the conductive light extraction unit 102 that further includes a protective layer 380 covering part of the metal layer 110 where is not covered by the first electrode 170 and filling the holes 160. The above-mentioned protective layer 380 may be made of transparent materials such as epoxy resin or polyamide (PI), insulation material, or fluorescent powder material to block water or oxygen in the air so that the components are free from being exposed to a general environment and thereby affecting the reliability of the components.

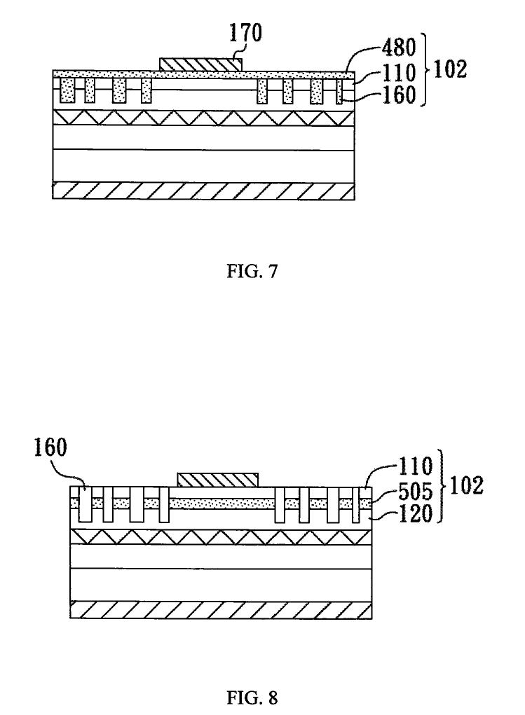

FIG. 7 shows a structural view of the optoelectronic device in accordance with a fourth embodiment of the present application. The difference between the fourth embodiment and the first embodiment lies in the conductive light extraction unit 102 that further includes a transparent conductive layer 480 covering the metal layer 110 and filling the holes 160. The transparent conductive layer 480 is fabricated by electron beam, sputtering or other chemical deposition methods. The thickness of the transparent conductive layer 480 is in the range of 40 nm to 1000 nm, and the transparent conductive layer 480 has transmittance beyond 90%, and is made of indium tin oxide (ITO) or zinc oxide (ZnO).

FIG. 8 shows a structural view of the optoelectronic device in accordance with a fifth embodiment of the present application. The difference between the fifth embodiment and the first embodiment lies in the conductive light extraction unit 102 that further includes an ohmic contact layer 505 located between the metal layer 110 and the n-type cladding layer 120. The ohmic contact layer 505 is made of Ni/Au to form a good ohmic contact layer between the metal layer 110 and the n-type cladding layer 120. The holes 160 penetrate through the metal layer 110, the ohmic contact layer 505, and the n-type cladding layer 120. Similarly, an ohmic contact layer can also be disposed between the metal layer 110 and the n-type cladding layer 120 in the foregoing four embodiments of the present application.

Because of the holes 160 defined in the conductive light extraction unit 102, the current can be rapidly diffused not only in the horizontal direction but also in the vertical direction so that the light extraction efficiency of the components can be effectively enhanced.

In the above-mentioned embodiments, the holes 160 are defined in the conductive light extraction unit 102 by ion etching, dry etching, chemical etching or nano-imprinting technologies. The sizes of the holes 160 are not necessarily the same, and the diameter of the holes 160 is between 0.1 μm and 5 μm. At the same time, the arrangement of the holes 160 is in periodic or a periodic order, or other artificial design patterns.

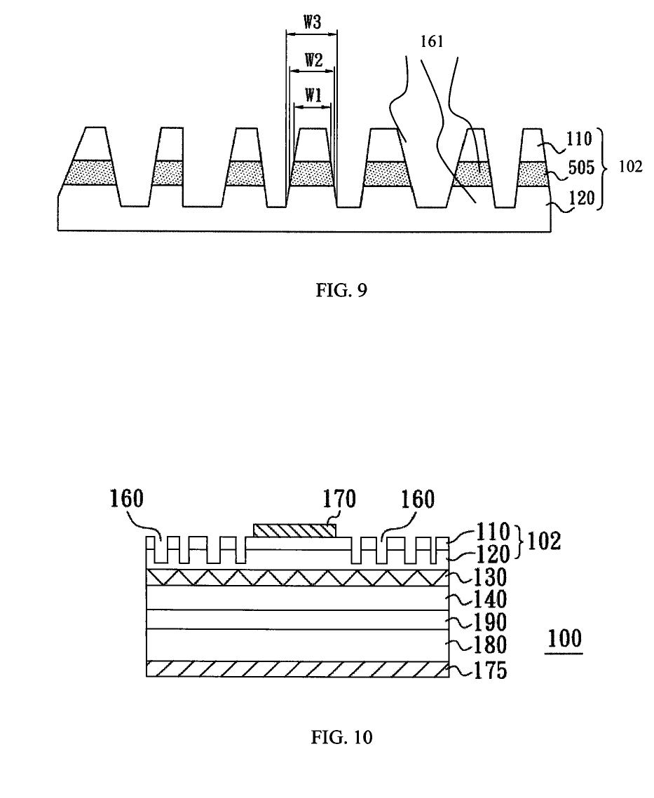

Furthermore, in the fifth embodiment, after the holes 160 are defined in the conductive light extraction unit 102, a plurality of patterned regions 161 is formed in the conductive light extraction unit 102 wherein each patterned region 161 contains the layers forming the light extraction unit 102. For each pattern region 161, the ratio of the bottom width of one layer and the bottom width of the adjacent layer is in the range of 0.7 to 1.3. As shown in FIG. 9, in a patterned region 161, the bottom width of the metal layer 110 is W1, the bottom width of the ohmic contact layer 505 is W2, and the bottom width of the n-type cladding layer 120 is W3. It is obvious to tell from FIG. 9 that W1 is less than W2, and W2 is less than W3. Namely, W1<W2<W3. And, the value of W1/W2 or W2/W3 is between 0.7 to 1.3.

FIG. 10 shows a structural view of the optoelectronic device in accordance with a sixth embodiment of the present application. The difference between the sixth embodiment and the first embodiment lies in the substrate 150 in the first embodiment is replaced by a binder layer 190 and a functional substrate 180. This substrate structure is formed by the substrate transfer process. The functional substrate 180 is able to dissipate heat, conduct electricity, or transparent like ceramic substrate, copper substrate, or sapphire substrate.

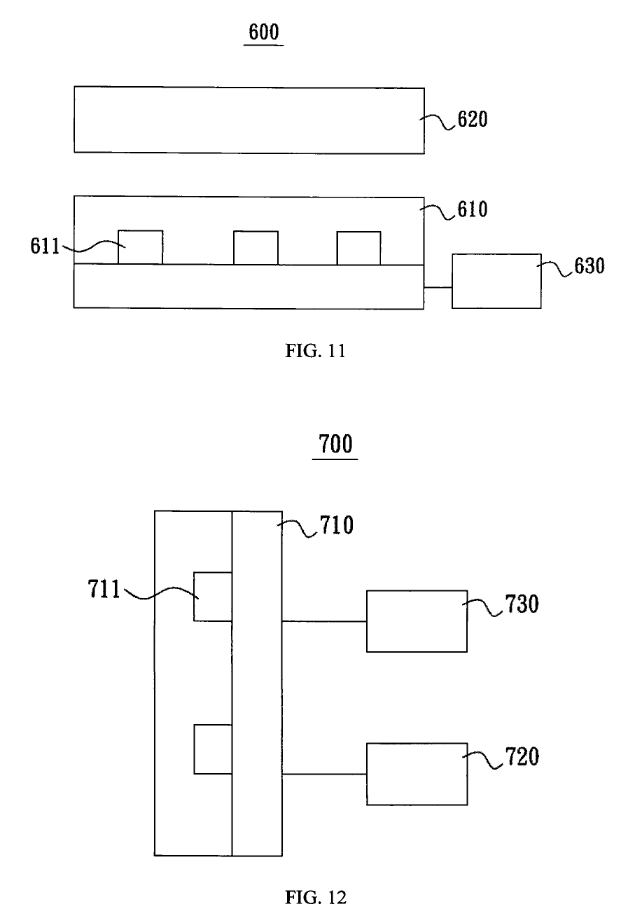

FIG. 11 shows a structure of a backlight module in accordance with the present application. A backlight module apparatus 600 includes a light source device 610 constituted by an optoelectronic device 611 in any of the above embodiments of the present application; an optical device 620 placed on a light extraction path of the light source device 610, and extracting the light after the appropriate treatment; and a power supply system 630 providing power for the light source device 610.

FIG. 12 shows a structure view of an illumination apparatus of the present application. The above-mentioned illumination apparatus 700 may be a car lamp, a street lamp, a flashlight, a road lamp, an indication lamp and so on. The illumination apparatus 700 includes a light source device 710 which is constituted by an optoelectronic device 711 in any of the above embodiments of the present application; a power supply system 720 providing power for the light source device 710; and a control component 730 for controlling power input to the light source device 710.

The above description is given by way of example, and not limitation. Given the above disclosure, one person having ordinary skill in the art could devise variations that are within the scope and spirit of the application disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. An optoelectronic device comprising:
a substrate;
a first cladding layer, an active layer and a conductive light extraction unit formed on the substrate, wherein the conductive light extraction unit comprising a second cladding layer formed on the active layer and a metal layer formed on the second cladding layer; and
a plurality of holes comprising a plurality of openings defined in the metal layer and extending to the second cladding layer.

2. The optoelectronic device according to claim 1, wherein the area of each of the plurality of openings is different.

3. The optoelectronic device according to claim 1, wherein distribution of the plurality of holes is irregular.

4. The optoelectronic device according to claim 1, wherein the optoelectronic device further comprising a first electrode, and the conductive light extraction unit further comprising a finger-like conductive body located between the first electrode and the metal layer wherein the finger-like conductive body comprises a junction portion and an extension portion extending outwards from the junction portion.

5. The optoelectronic device according to claim 4, wherein the extension portion and the junction portion are made of metal.

6. The optoelectronic device according to claim 4, wherein the extension portion and the junction portion are the same material as the first electrode.

7. The optoelectronic device according to claim 5, wherein the extension portion and the junction portion are made of gold, silver, copper, or aluminum.

8. The optoelectronic device according to claim 1, further comprising a protective layer formed on the metal layer.

9. The optoelectronic device according to claim 8, wherein the protective layer is made of epoxy resin, polyamide (PI), transparent insulation material, or fluorescent powder material.

10. The optoelectronic device according to claim 1, further comprising a transparent conductive layer formed on the metal layer.

11. The optoelectronic device according to claim 1, wherein the transparent conductive layer is made of indium tin oxide (ITO) or zinc oxide (ZnO).

12. The optoelectronic device according to claim 11, wherein the transparent conductive layer is formed by electron beam, sputtering or chemical deposition method.

13. The optoelectronic device according to claim 1, further comprising an ohmic contact layer disposed between the metal layer and the second cladding layer.

14. The optoelectronic device according to claim 1, wherein the conductive light extraction unit comprising a plurality of patterned regions defined by the holes and containing the layers forming the conductive light extraction unit wherein the ratio of the bottom widths of any two adjacent layers in each of the patterned regions is in the range of 0.7 to 1.3.

15. The optoelectronic device according to claim 1, wherein the diameter of the holes is in the range of 0.1 μm to 5 μm.

16. An backlight module apparatus comprising:
a light source device constituted by an optoelectronic device according to claim 1;
an optical device placed on a light extraction path of the light source device; and
a power supply system providing power for the light source device.

17. An illumination apparatus comprising:
a light source device constituted by an optoelectronic device according to claim 1;
a power supply system providing power for the light source device; and
a control component configured for controlling power input the to light source device.
